(19) United States
(12) Patent Application Publication
(10) Pub. No.: US 2015/0228461 A1
(43) Pub. Date: Aug. 13, 2015

(54) PLASMA TREATMENT APPARATUS AND METHOD

(71) Applicant: JCU CORPORATION, Tokyo (JP)

(72) Inventors: Shinji FUKAZAWA, Kawasaki-shi (JP); Keisuke Asano, Kawasaki-shi (JP); Hiroyuki Ueyama, Kawasaki-shi (JP)

(21) Appl. No.: 14/691,776

(22) Filed: Apr. 21, 2015

Related U.S. Application Data
(63) Continuation of application No. PCT/JP2013/074607, filed on Sep. 12, 2013.

(30) Foreign Application Priority Data
Oct. 24, 2012 (JP) PCT/JP2012/077454

(51) Int. Cl. H01J 37/32

(52) U.S. Cl. CPC H01J 37/32532; H01J 37/3244; H01J 37/32036; H01J 37/32541; H01J 37/32568

(57) ABSTRACT

A substrate held by a holder is housed in a treatment chamber. An electrode set is disposed so as to face a surface of the substrate. Each electrode set consists of a first electrode section and a second electrode section. Each of the first and second electrode sections consists of high-frequency electrodes and/or ground electrodes. Process gas emitted through introduction ports is fed between the electrodes to generate plasma. The generated plasma is used to remove contaminated substances adhered to the surface of the substrate.

### CROSS-REFERENCE TO RELATED APPLICATIONS

This application is a Continuation of PCT International Application No. PCT/JP2013/074607 filed on Sep. 12, 2013, which claims priority under 35 U.S.C §119 (a) to PCT International Application No. PCT/JP2012/077454 filed on Oct. 24, 2012. The above application is hereby expressly incorporated by reference, in its entirety, into the present application.

### BACKGROUND OF THE INVENTION

1. Field of the Invention

The present invention relates to a plasma treatment apparatus and method for subjecting a workpiece to plasma treatment in a treatment chamber in a vacuum state.

2. Description Related to the Prior Art

A plasma treatment apparatus for subjecting a workpiece such as a substrate to various kinds of treatment using plasma in a treatment chamber in a vacuum state is known. As the plasma treatment, there are, for example, cleaning for removing contaminated substances adhered to a surface of the substrate, etching, desmearing for removing resin residues (i.e. smears) adhered to a wall surface of a through-hole formed in the substrate, descumming for removing residues (i.e. scum) of resist (e.g. organic substances) adhered to the surface of the substrate, and the like. In the plasma treatment, the inside of the treatment chamber is brought into a vacuum state, and in a state that high-frequency voltage is applied between a pair of electrodes from a high-frequency power source, process gas is introduced into the treatment chamber. Thereby, the process gas is made into plasma. Then, radicals and ions contained in the generated plasma come in contact with or collide with the surface of the workpiece, and thereby the contaminated substances adhered to the surface of the workpiece are removed, namely, the surface of the workpiece is cleaned.

In a plasma treatment apparatus disclosed in Japanese Patent Laid-Open Publication No. 8(1996)-037178, a substrate as a workpiece is disposed between a pair of flat-plate electrodes in a treatment chamber and subjected to asking treatment. One of the pair of flat-plate electrodes is applied with high-frequency voltage, and the other of the pair of flat-plate electrodes is grounded. In a state that the substrate is mounted on the grounded electrode, process gas is introduced into the treatment chamber, and plasma is generated, so as to subject the substrate to the treatment. Further, according to Japanese Patent Laid-Open Publication No. 8(1996)-115903, in the case of performing etching treatment using plasma, a substrate is disposed at the side of a high-frequency electrode to which high-frequency voltage is applied, and in a state that a gas introduction port disposed so as to face the high-frequency electrode is grounded, the process gas is emitted through the introduction port toward the substrate.

A plasma treatment apparatus in which one electrode array is disposed so as to face a substrate as a workpiece is also known. In the plasma treatment apparatus, electrodes different in polarity are alternately arranged in the electrode array. High-frequency voltage is applied between the electrodes so as to generate plasma around the electrode array. Then, radicals and ions are supplied from the generated plasma region to the surface of the substrate so as to subject the surface of the substrate to the treatment. An interval between the electrodes in the electrode array is appropriately determined together with electrical power to be outputted from the high-frequency power source, frequency, speed for introducing the process gas, and the like, in consideration of an interval between the electrode array and the substrate, the content of the treatment, and required treatment speed.

Japanese Patent Laid-Open Publication No. 4(1992)-358076 discloses an atmospheric-pressure plasma treatment apparatus. The atmospheric-pressure plasma treatment apparatus is an atmospheric-pressure plasma reaction apparatus including a gas introduction port for introducing process gas into a treatment chamber kept at an atmospheric pressure, at least two electrodes parallel to each other disposed in a downstream side from the gas introduction port in a process gas flow direction, and a support for supporting the substrate as the workpiece in a downstream side from the electrodes in the process gas flow direction. In the atmospheric-pressure plasma reaction apparatus, the process gas is fed between the electrodes to be made into plasma, and the plasma is conveyed to the downstream side by the gas flow, so as to subject the surface of the substrate supported on the support base to the treatment. Mixed gas of rare gas and reactive gas is used as the process gas.

Incidentally, in the configuration in which the substrate as the workpiece is disposed between the pair of electrodes as disclosed in Japanese Patent Laid-Open Publication No. 8(1996)-037178 and Japanese Patent Laid-Open Publication No. 8(1996)-115903, the substrate is disposed in the plasma. In this case, since the amount of plasma applied to the surface of the substrate becomes too much, the substrate tends to be damaged easily. Further, it is not easy to adjust the amount and the distribution of the plasma on the surface of the substrate, and it is difficult to uniformly subject the surface of the substrate to the treatment. Furthermore, since the temperature of the substrate is increased due to the heat generation of the electrodes, the substrate is damaged by the temperature in some cases.

Moreover, in the plasma treatment apparatus in which one electrode array is disposed, the plasma treatment can be performed without disposing the workpiece between the pair of electrodes different in polarity. Therefore, the substrate is not damaged unlike the above case. However, since the plasma region formed around the electrode array is thin and the amount of generated plasma is small, the treatment cannot be efficiently performed.

In contrast, in the atmospheric-pressure plasma treatment apparatus disclosed in Japanese Patent Laid-Open Publication No. 4(1992)-358076, the amount of plasma on the surface of the substrate can be easily made uniform. However, since the plasma is generated at the atmosphere pressure, the plasma generated between the electrodes easily disappears due to the existence of gas which is not made into plasma, and it is impossible to supply the surface of the substrate with sufficient amount of plasma. Therefore, the treatment time becomes too long, and thereby the substrate tends to be affected by the heat of the electrodes.

### SUMMARY OF THE INVENTION

In view of the foregoing, an object of the present invention is to provide a plasma treatment apparatus and method capable of supplying a workpiece with a sufficient amount of plasma and facilitating adjustment of an amount of plasma to be supplied at the time of subjecting the workpiece to the plasma treatment.

To achieve the above and other objects of the present invention, a plasma treatment apparatus for performing plasma treatment in a treatment chamber brought into a vacuum state of the present invention includes an introduction port, a power source, and an electrode set. The process gas is emitted through the introduction port into the treatment chamber. The power source outputs high-frequency voltage intended for generating the plasma. The electrode set includes a first electrode section and a second electrode section so as to generate the plasma by exciting the process gas by the high-frequency voltage outputted from the power source. The first electrode section having a plurality of electrodes in the shape of a rod arranged in parallel with one another at predetermined intervals is disposed to face the workpiece in a state of being separated from the workpiece. The second electrode section is disposed to face the workpiece across the first electrode section in a state of being separated from the first electrode section.

Preferably, the second electrode section has a plurality of electrodes in the shape of a rod arranged in parallel with one another at predetermined intervals, and the electrodes in each of the first electrode section and the second electrode section are arranged in parallel with the surface of the workpiece.

The introduction port is preferably disposed to be opposed to the workpiece across the electrode set such that the process gas is emitted toward the workpiece through the electrode set.

Preferably, the plasma treatment apparatus further includes an exhaust port for exhausting air from the treatment chamber, and the exhaust port is disposed at a position facing the introduction port across the workpiece. The process gas is emitted through the introduction port toward the electrode set in a direction in which the electrodes of the first and second electrode sections are aligned or in an axial direction of the electrodes.

Further, it is preferable that the electrodes different in polarity are alternately arranged to constitute each of the first and second electrode sections.

Furthermore, it is preferable that a polarity of each of the electrodes arranged in the first electrode section is different from a polarity of each of the electrodes arranged in the second electrode section.

Further, the second electrode section is preferably an inner wall surface of the treatment chamber. The high-frequency voltage is applied from the power source to the electrode set, in which a polarity of each of the electrodes of the first electrode section is different from a polarity of the inner wall surface, to generate the plasma.

Further, each of the electrodes of the first electrode section and the inner wall surface as ground electrodes are preferably parallel to the surface of the workpiece.

Preferably, the plasma treatment apparatus further includes an exhaust port for exhausting air from the treatment chamber, and the exhaust port is disposed at a position facing the introduction port across the first electrode section. The process gas is emitted through the introduction port toward the first electrode section in a direction in which the electrodes of the first electrode section are aligned or in an axial direction of the electrodes.

Further, the electrode set is preferably disposed at positions for sandwiching the workpiece.

Furthermore, the electrode set also may be disposed only at a position where the electrode set faces one surface of the workpiece.

Preferably, the plasma treatment apparatus further includes a holder for holding a pair of the workpieces superimposed to each other in a state that the surface of each of the workpieces is directed to the outside. The electrode set is disposed so as to face the surface of each of the pair of workpieces held by the holder.

Preferably, the plasma treatment apparatus further includes a holder for holding a plurality of workpieces in a state that the surface of each of the workpieces is directed to the electrode set.

Preferably, the plasma treatment apparatus further includes a flow channel control member disposed in the treatment chamber, for preventing the process gas emitted through the introduction port from flowing between the electrode set and the treatment chamber toward the exhaust port.

A plasma treatment method for performing plasma treatment in a treatment chamber brought into a vacuum state of the present invention includes an introducing step, a generating step, and a treatment step. In the introducing step, process gas is introduced into the treatment chamber. In the generating step, the introduced process gas is excited by an electrode set to generate plasma. The electrode set includes a first electrode section and a second electrode section. The first electrode section has a plurality of electrodes in the shape of a rod arranged in parallel with one another at predetermined intervals. The first electrode section is disposed so as to face the workpiece in a state of being separated from the workpiece. The second electrode section is disposed so as to face the workpiece across the first electrode section in a state of being separated from the first electrode section. In the treatment step, the workpiece is subjected to the treatment using the generated plasma.

Preferably, a plurality of electrodes in the shape of a rod are arranged in parallel with one another at predetermined intervals in the second electrode section, and the electrodes of each of the first electrode section and the second electrode section are arranged in parallel with the surface of the workpiece.

Further, in the introducing step, the process gas is preferably emitted toward the electrode set through the introduction port disposed to be opposed to the workpiece across the electrode set.

Furthermore, the second electrode section is preferably an inner wall surface of the treatment chamber. In the generating step, in a state that the polarity of each of the electrodes of the first electrode section is different from the polarity of the inner wall surface, high-frequency voltage is applied from the power source so as to generate the plasma.

Further, each of the electrodes of the first electrode section and the inner wall surface are preferably parallel to the surface of the workpiece.

Preferably, the plasma treatment method further includes an exhausting step for exhausting air from the treatment chamber while generating the plasma, and air is exhausted through an exhaust port disposed at a position facing the introduction port across the first electrode section. In the introducing step, the process gas is emitted through the introduction port toward the first electrode section in a direction in which the electrodes of the first electrode section are aligned or in an axial direction of the electrodes.

Further, the plasma may be generated in the electrode set disposed at positions for sandwiching the workpiece, so as to subject the workpiece to treatment using the plasma generated in each of the electrode sets in the treatment step.

According to the present invention, it is possible to supply the workpiece with plasma uniformly and sufficiently, and perform the treatment uniformly in a short time. Further, it becomes possible to readily adjust the amount of plasma to be supplied to the workpiece. Furthermore, it is possible to complete the plasma treatment in a short time and prevent damage to the workpiece caused by heat.

### BRIEF DESCRIPTION OF DRAWINGS

For more complete understanding of the present invention, and the advantage thereof, reference is now made to the subsequent descriptions taken in conjunction with the accompanying drawings, in which:

FIG. 1 is a perspective view illustrating an external appearance of a plasma treatment apparatus of the present invention;

FIG. 2 is a perspective view illustrating a state of each component in a treatment chamber;

FIG. 3 is a perspective view illustrating an electrode unit including a holder for holding a substrate;

FIG. 4 is an explanatory diagram illustrating electrical connections in a treatment unit;

FIG. 5 is an explanatory diagram showing an example, in which each electrode section consists of electrodes of the same type, and a first electrode section close to the substrate consists of ground electrodes;

FIG. 6 is an explanatory diagram showing an example, in which each electrode section consists of electrodes of the same type, and a first electrode section close to the substrate consists of high-frequency electrodes;

FIG. 7 is an explanatory diagram showing an example, in which each electrode set includes an electrode section composed of high-frequency electrodes and an electrode section composed of ground electrodes, and the positions of the electrode sections are deviated from each other in each electrode set;

FIG. 8 is an explanatory diagram showing an example, in which the high-frequency electrodes and the ground electrodes are displaced between the electrode sections;

FIG. 9 is an explanatory diagram showing an example, in which process gas is emitted through the electrode set toward a workpiece;

FIG. 10 is a perspective view showing an example, in which each of the electrodes is in the shape of a rectangular column;

FIG. 11 is an explanatory diagram showing an example, in which an inside of the electrode is hollow so as to be cooled by cooling water;

FIG. 12 is an explanatory diagram showing an example, in which a pair of electrode plates each having a lattice shape is used;

FIG. 13 is an explanatory diagram showing an example, in which a mesh is adopted to constitute the lattice shape of the pair of electrode plates;

FIG. 14 is an explanatory diagram showing an example, in which flow channel control plates are disposed such that the process gas is emitted in an arrangement direction of the electrodes of the electrode sections;

FIG. 15 is an explanatory diagram showing an example, in which the flow channel control plates are disposed such that the process gas is emitted toward the workpiece through the electrode sets;

FIG. 16 is a perspective view showing an example, in which two substrates, each of which has one surface to be treated, are superimposed to each other and held by a holder;

FIG. 17 is a perspective view showing an example, in which a plurality of substrates of small size are held by the holder;

FIG. 18 is a perspective view showing an example, in which two substrates are disposed so as to sandwich the electrode set therebetween;

FIG. 19 is a perspective view showing an example, in which each of a vacuum tank and an electrode unit is divided into two parts in a vertical direction;

FIG. 20 is an explanatory diagram showing an example, in which the electrode set is disposed so as to face only one surface of the substrate;

FIG. 21 is an explanatory diagram showing an example, in which each of the electrodes is not grounded;

FIG. 22 is a cross sectional view showing an example, in which an inner surface wall of the treatment chamber is used as electrodes of a second electrode section; and

FIG. 23 is a cross sectional view showing an example, in which the inner surface wall of the treatment chamber is used as ungrounded electrodes.

### DESCRIPTION OF THE PREFERRED EMBODIMENTS

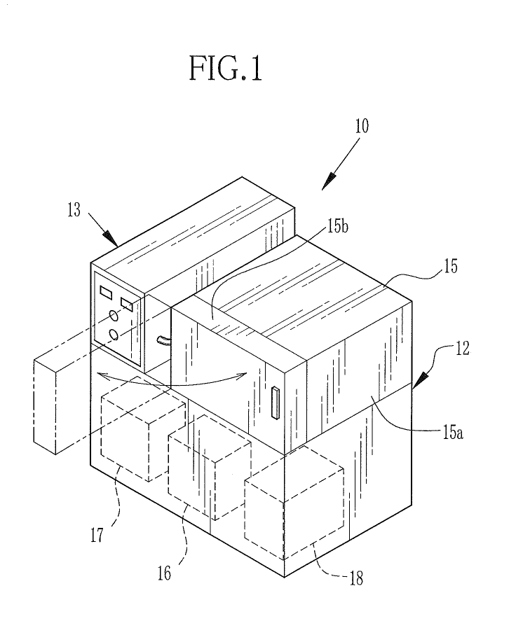

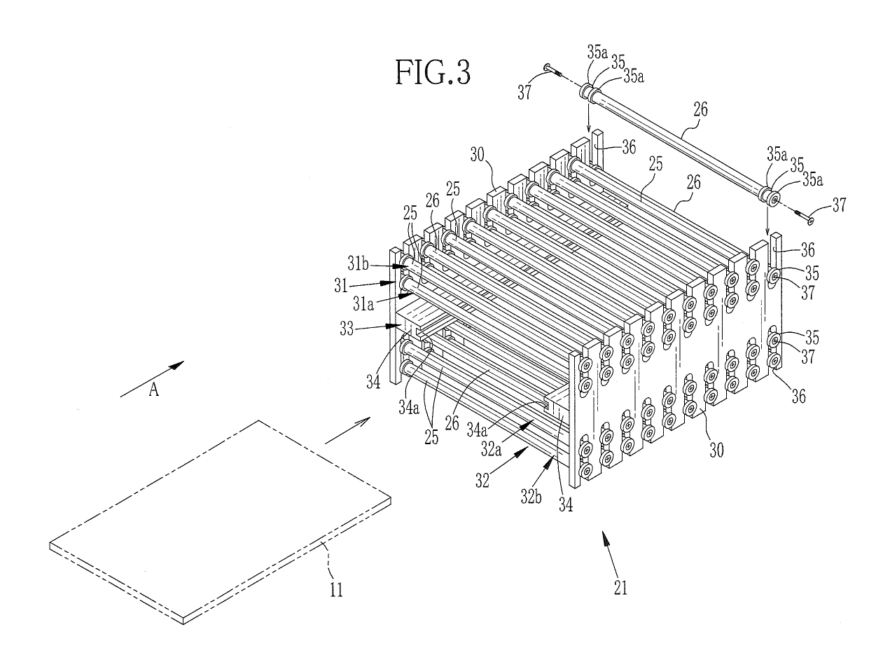

As shown in FIG. 1, a plasma treatment apparatus 10 of the present invention subjects a workpiece to plasma treatment. In this example, a surface (specifically, two surfaces) of a substrate 11 (see FIG. 3) which is a plate-like workpiece is a surface to be treated, and subjected to plasma treatment. The workpiece may be not only the substrate 11 but also a lead frame or the like. Additionally, a plate-like workpiece and a three-dimensional workpiece, such as an object having an uneven surface and a substrate or the like having a surface on which semiconductor chips are mounted, may be subjected to the plasma treatment.

Further, in this example, as the plasma treatment, plasma cleaning for removing resin or the like adhered to the surface of the substrate is described hereinbelow. However, examples of the plasma treatment may include cleaning of electrodes of the semiconductor chips mounted on the surface of the substrate or the like, resist etching, descumming, desmearing, surface modification, and the like.

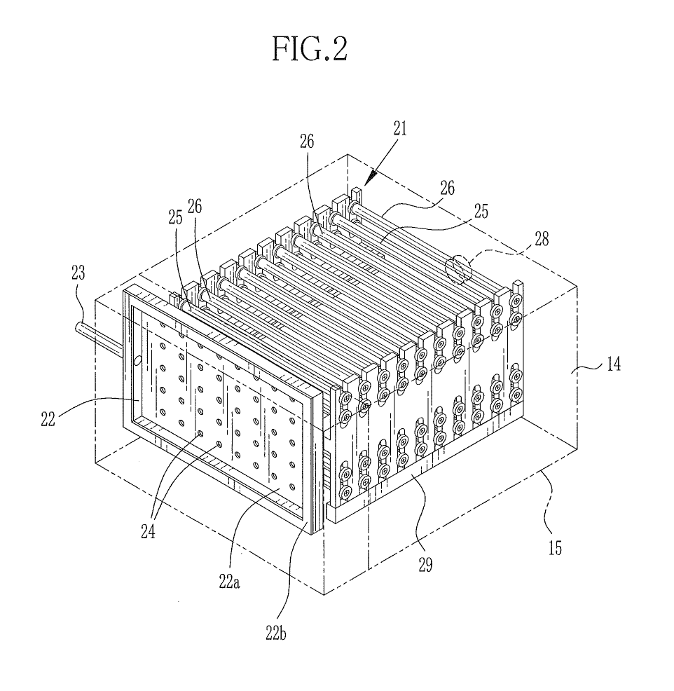

The plasma treatment apparatus 10 includes a treatment unit 12, a control unit 13 composed of circuits for controlling the treatment unit 12, and the like. The treatment unit 12 consists of a vacuum tank 15 in which a treatment chamber 14 (see FIG. 2) is formed, electrodes disposed in the treatment chamber 14, a vacuum pump 16, a gas feeder 17, a high-frequency power source 18, and the like. The vacuum tank 15 has a box shape and is made of stainless, for example. The vacuum tank 15 consists of a main body 15a and a lid 15b attached to the front side of the main body 15a. The lid 15b is pivotable between a closed position shown by solid lines and an opened position shown by chain double-dashed lines.

During the plasma treatment, the lid 15b is set to the closed position, such that the treatment chamber 14 is brought into an airtight state. Upon shifting of the lid 15b to the opened position, the treatment chamber 14 is opened. Consequently, the substrate 11 can be carried into and carried out of the treatment chamber 14 through an opening (not shown in the drawing) exposed at the front side of the main body 15a, and additionally, an electrode unit 21 (see FIG. 2) also can be carried into and carried out of the treatment chamber 14 for the purpose of adjustment or cleaning.

The vacuum pump 16 exhausts air from the treatment chamber 14, such that a degree of vacuum in the treatment chamber 14 falls within the range of 10 Pa to 30 Pa, for example. Further, the vacuum pump 16 continuously exhausts air from the treatment chamber 14 during the plasma treatment, such that a predetermined degree of vacuum is kept in the treatment chamber 14. The gas feeder 17 supplies process gas to be introduced into the treatment chamber 14. The process gas is mixed gas of carbon tetrafluoride (CF4) and oxygen (O2), for example. Note that, the process gas is arbitrarily selected in accordance with the content of the plasma treatment, the workpiece, and the like. Nitrogen gas, oxygen gas, hydrogen gas, argon gas, or mixed gas of another combination of gases may be used, instead of the mixed gas described above.

A high-frequency power source 18 outputs high-frequency voltage as plasma generation voltage for generating plasma. The frequency of the high-frequency voltage outputted from the high-frequency power source 18 is in the range of 40 kHz to several hundred kHz, for example. Note that, the frequency of the high-frequency voltage is not limited to the above-described range, and may be arbitrarily set in accordance with the content of the plasma treatment and the like. For example, the frequency of the high-frequency voltage may be higher or lower than the above-described range.

As shown in FIG. 2, not only the electrode unit 21 described above but also a gas introducing section 22 is disposed in the treatment chamber 14. The gas introducing section 22 is attached to an inner surface of the lid 15b so as to pivot together with the lid 15b. The gas introducing section 22 has a box shape. The process gas is supplied from the gas feeder 17 through a gas supply tube pipe 23 to a hollow portion of the gas introducing section 22. A posteriorly-directed surface of the gas introducing section 22, that is, a surface 22a of the gas introducing section 22 facing the electrode unit 21, includes a plurality of minute introduction ports 24 each having a diameter of approximately 1 mm, for example. Note that, the gas introducing section 22 is attached to the lid 15b through an insulating plate 22b, such that the gas introducing section 22 is electrically insulated from the vacuum tank 15.

The process gas supplied to the hollow portion of the gas introducing section 22 is horizontally emitted toward the electrode unit 21 through each of the introduction ports 24. Thereby, the process gas is emitted in a direction parallel to the substrate 11 held horizontally in the electrode unit 21 as well as in a direction in which electrodes are arranged in an electrode section to be described later, so as to be introduced into the treatment chamber 14. Further, the plurality of introduction ports 24 are uniformly distributed on an area of the surface 22a facing the electrode unit 21. Thereby, the process gas is emitted like a shower so as to be uniformly supplied to the inside of the electrode unit 21. Note that, instead of introducing the process gas like a shower, the process gas may be introduced through one or several introduction ports 24.

The electrode unit 21 includes a plurality of high-frequency electrodes 25 and ground electrodes 26 for generating plasma. The electrode unit 21 is disposed substantially at the center of the treatment chamber 14, such that the front side of the electrode unit 21 faces the surface 22a of the gas introducing section 22. Further, the substrate 11 is held inside the electrode unit 21. The electrode unit 21 is attached to the inside of the vacuum tank 15 through an insulating member 29, and is electrically insulated from the vacuum tank 15.

An exhaust port 28 is formed on a posterior wall of the treatment chamber 14 so as to be opposed to the introduction ports 24 across the substrate 11 held in the electrode unit 21. The vacuum pump 16 is connected to the exhaust port 28, such that air is exhausted from the treatment chamber 14 through the exhaust port 28. Since the electrode unit 21 is disposed between the introduction ports 24 and the exhaust port 28 as described above, the process gas emitted through each of the introduction ports 24 flows between the electrodes in the electrode unit 21, such that plasma is generated uniformly in the electrode unit 21.

As shown in FIG. 3, the electrode unit 21 consists of a pair of side plates 30, an upper electrode set 31, a lower electrode set 32, a holder 33 for holding the substrate 11, and the like. The pair of side plates 30 is fixed so as to face each other in parallel by fixing one end of each of the electrodes 25 and 26 to one of the side plates 30 and the other end of each of the electrodes 25 and 26 to the other of the side plates 30 as described later. Note that, each of the electrodes 25 and 26 is assembled to the side plates 30 in an electrically insulating manner.

A rail member 34 constituting the holder 33 is formed on an inner surface of each of the side plates 30. Each of the rail members 34 horizontally extends from the front side to the rear side of the electrode unit 21 at the center in a height direction of the side plate 30. A groove 34 is formed at the front end of each of the rail members 34. Both side edges of the substrate 11 to be treated are inserted into the grooves 34a from the front side of the electrode unit 21, and thereby the substrate 11 is horizontally held in the electrode unit 21 in a state that the surfaces of the substrate 11 to be treated are respectively directed upward and downward, i.e., respectively directed to the upper electrode set 31 and the lower electrode set 32.

Each of the upper electrode set 31 and the lower electrode set 32 is intended to generate plasma by exciting the process gas. Each of the upper electrode set 31 and the lower electrode set 32 consists of a plurality of the high-frequency electrodes 25 and a plurality of the ground electrode 26. Each of the electrodes 25 and 26 is made of metal having conductive properties, such as aluminum. Each of the electrodes 25 and 26 is in the shape of a rod having a circular cross section (i.e. in a cylindrical shape). The electrodes 25 and 26 are the same in shape and size. High-frequency voltage is applied to the high-frequency electrodes 25 from the high-frequency power source 18, and the ground electrodes 26 are grounded. Each of the high-frequency electrodes 25 is referred to as a first electrode, and each of the ground electrodes 26 is referred to as a second electrode.

The upper electrode set 31 is disposed above the holder 33, i.e., at the upper-surface side of the substrate 11, in a state of facing the upper surface of the substrate 11. The upper electrode set 31 includes a first electrode section 31a and a second electrode section 31b arranged vertically in two stages. The first electrode section 31a is disposed so as to face the upper surface (i.e. the surface to be treated) of the substrate 11 in a state of being separated from the upper surface of the substrate 11. The second electrode section 31b is disposed above the first electrode section 31a so as to face the upper surface of the substrate 11 across the first electrode section 31a in a state of being separated from the first electrode section 31a. Adjustment is performed so as to keep a predetermined interval between the first electrode section 31a and the second electrode section 31b, such that the process gas flows between the first electrode section 31a and the second electrode section 31b.

Each of the first electrode section 31a and the second electrode section 31b has an electrode array in which a plurality of the high-frequency electrodes 25 and a plurality of the ground electrodes 26 are arranged to be separated from each other in a process gas emitting direction shown by an arrow A. Further, the high-frequency electrodes 25 and the ground electrode 26 in each of the first electrode section 31a and the second electrode section 31b are parallel to the substrate 11. Further, the high-frequency electrodes 25 and the ground electrodes 26 are arranged in a state that a long side of each of the electrodes 25 and 26 extends along a direction orthogonal to the process gas emitting direction, namely, an axial direction of the electrodes 25 and 26 is orthogonal to the process gas emitting direction. In this example, in each of the first electrode section 31a and the second electrode section 31b, the high-frequency electrode 25 and the ground electrode 26 are alternatively arranged in the process gas emitting direction, and the electrodes of the same type are arranged in the vertical direction.

The lower electrode set 32 is disposed at the lower-surface side of the substrate 11. The lower electrode set 32 includes a first electrode section 32a and a second electrode section 32b disposed under the first electrode section 32a in the vertical direction. The arrangement of the high-frequency electrodes 25 and the ground electrodes 26 in the lower electrode set 32 is the same as that in the upper electrode set 31. Namely, the first electrode section 32a is disposed so as to face the lower surface of the substrate 11 in a state of being separated from the lower surface of the substrate 11. The second electrode section 32b is disposed so as to face the lower surface of the substrate 11 across the first electrode section 32a in a state of being separated from the first electrode section 32a. Consequently, each of the first electrode section 32a and the second electrode section 32b has the electrode array.

Each of the electrode sections is disposed so as to face the upper surface of the substrate 11 as the surface to be treated as described above. However, the surface of the workpiece to which each of the electrode sections should be opposed is not always the surface to be treated. Namely, in the case of desmearing for removing resin residues adhered to a through-hole of a substrate or a wall surface of a via hole, the surface to be treated is the through-hole formed in the substrate or the wall surface of the via hole. In this case, plasma should be primarily supplied to the surface (specifically, upper surface or lower surface) of the substrate, in which an opening such as the through-hole is formed, and to which each of the electrode sections 31a and 31b should be opposed. Plasma is supplied through the opening such as the through-hole formed in the surface of the substrate to the inside of the substrate.

In each of the electrode sections, the high-frequency electrodes 25 and the ground electrodes 26 are arranged in an area larger than the surface (specifically, upper surface and lower surface) of the substrate 11. The high-frequency electrodes 25 and the ground electrodes 26 are disposed so as to face the substrate 11 in a state of being separated from the substrate 11 and covering the surface of the substrate 11. Thereby, the surface (specifically, upper surface or lower surface) of the substrate 11 surely faces a plasma region in each of the upper electrode set 31 and the lower electrode set 32, and the surface of the substrate 11 is uniformly subjected to the plasma treatment using the plasma (radicals and ions) supplied from the plasma region.

A bushing 35 made of an insulating material is attached to both ends of each of the high-frequency electrode 25 and the ground electrode 26. The bushing 35 is fit into a mounting groove 36 having a U-shape provided at the side plate 30. Thereby, each of the electrodes 25 and 26 is assembled to the side plates 30 so as to be movable in the vertical direction in an insulated state. The bushing 35 has a pair of flanges 35a, one of which is disposed outside the sideplate 30 and the other of which is disposed inside the side plate 30.

A screw 37 is threadably mounted on the both ends of each of the high-frequency electrode 25 and the ground electrode 26 through the bushing 35 from the outside of the side plate 30, and the bushing 35 is elastically deformed, such that the side plate 30 is sandwiched between the flanges 35a disposed inside and outside the side plate 30. Thereby, the high-frequency electrodes 25 and the ground electrodes 26 are fixed to the side plates 30. The high-frequency electrodes 25 and the ground electrodes 26 are moved in the vertical direction by loosening the screws 37, so as to adjust the interval between the electrodes in the vertical direction (i.e. in the direction vertical to the substrate 11) and the interval between the substrate 11 and each of the electrodes 25 and 26. Note that, the bushing 35 divided into two sections, one of which is located inside the side plate 30 and the other of which is located outside the side plate 30, may be used.

By adjusting the interval between the electrodes in the vertical direction, that is, in the direction vertical to the surface of the substrate 11 as described above, it is possible to adjust the ease of passage of the process gas into each of the electrode sets 31 and 32 and the density and distribution of the plasma in each of the electrode sets 31 and 32. Additionally, by adjusting the interval between the substrate 11 and each of the electrodes 25 and 26, it is possible to adjust the closeness between the substrate 11 and the plasma in each of the electrode sets 31 and 32. Accordingly, it is possible to adjust each of the uniformity of the plasma treatment applied to the surface of the substrate 11 and the treatment speed to a desired level.

In order to flow the process gas smoothly in each of the electrode sets 31 and 32, the interval between the electrodes in the vertical direction seen from the process gas emitting direction in each of the electrode sets 31 and 32 is preferably at least the width of each of the electrodes seen from the process gas emitting direction. In this example, it is preferable that each of the interval between the high-frequency electrodes 25 aligned in the vertical direction and the interval between the ground electrodes 26 aligned in the vertical direction is at least a diameter of each of the electrodes 25 and 26. Further, in the case where the substrate 11 is sandwiched between one pair of the electrode sets 31 and 32 as with this example, in order to prevent generation of plasma between the electrode of one of the electrode sets and the electrode of the other of the electrode sets, namely, between the electrode of the electrode set 31 and the electrode of the electrode set 32, the electrode sets 31 and 32 are preferably arranged symmetrically with respect to the substrate 11.

Note that, the configuration of the electrode unit 21 described above is one example. For example, the upper electrode set and the lower electrode set may be configured as separate units as described later. Further, although the high-frequency electrodes 25 and the ground electrodes 26 are movable in the vertical direction, it is also preferable that the high-frequency electrodes 25 and the ground electrodes 26 are movable in a horizontal direction (i.e. in a back-and-forth direction) so as to adjust the interval between the electrodes adjacent to each other in the back-and-forth direction. Furthermore, each of the upper electrode set 31 and the lower electrode set 32 may have three or more electrode arrays (electrode sections) layered in a state of being separated from one another. Further, although the direction for emitting the process gas through the introduction ports 24 corresponds to the direction in which the electrodes 25 and 26 are aligned in each of the electrode sections in this example, the process gas may be emitted in the axial direction of each of the electrodes 25 and 26.

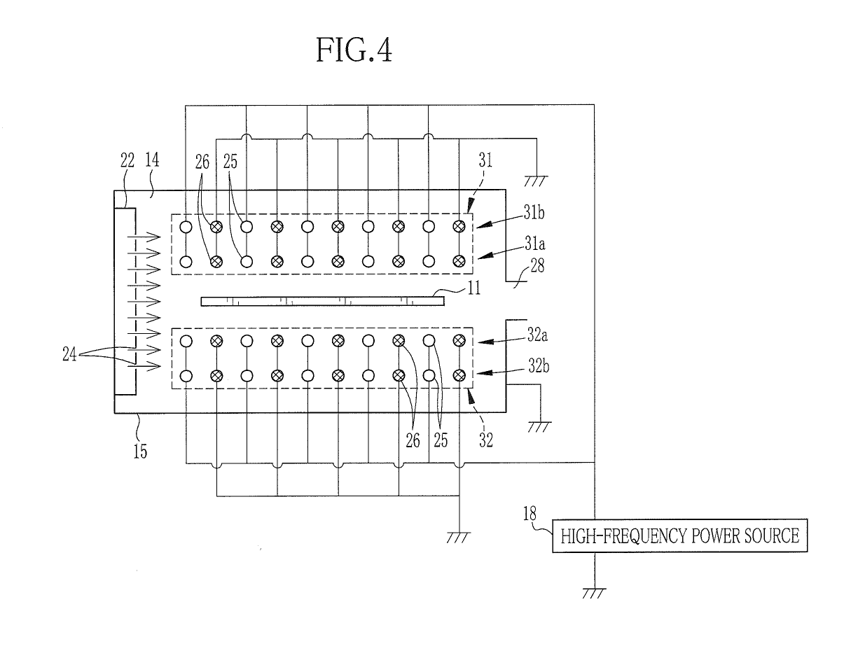

As shown in FIG. 4, high-frequency voltage is applied to the high-frequency electrodes 25 each of which is connected to the high-frequency power source 18 via a wiring (not shown in the drawing) in the treatment chamber 14, and the ground electrodes 26 are grounded. The vacuum tank 15 is also grounded. Since the gas introducing section 22 and the side plates 30 of the electrode unit 21 are fixed to the vacuum tank 15 through the insulating plate 22b and the insulating member 29, respectively, as described above, the gas introducing section 22 and the side plates 30 of the electrode unit 21 are not electrically connected to the high-frequency power source 18 and are not grounded. In the similar manner, the holder 33 and the substrate 11 held by the holder 33 are not electrically connected to the high-frequency power source 18 and are not grounded.

Next, the operation of the above-described configuration will be explained hereinbelow. The plasma treatment is performed upon actuation of each component under the control of the control unit 13. At first, after it is confirmed that the pressure inside the treatment chamber 14 is atmospheric pressure, the lid 15b is pivoted to the opened position. Next, the substrate 11 held by the holder 33, which has been subjected to the treatment, is taken out from the treatment chamber 14. Thereafter, the substrate 11 to be treated is inserted into the holder 33 and set to the inside of the treatment chamber 14, and then the lid 15b is pivoted to the closed position. Note that, the treatment chamber 14 may be automatically opened/closed, and the substrate 11 may be automatically carried into and carried out of the treatment chamber 14 with use of a robot arm or the like.

Upon actuation of the vacuum pump 16, air is exhausted from the treatment chamber 14 until a predetermined degree of vacuum is achieved. When the predetermined degree of vacuum is achieved, the supply of the process gas by the gas feeder 17 is started, and the application of the high-frequency voltage to the high-frequency electrodes 25 by the high-frequency power source 18 is also started. The process gas is introduced through each of the introduction ports 24 into the treatment chamber 14. Upon application of the high-frequency voltage to the high-frequency electrodes 25, the process gas is excited into plasma in an electric field generated between the high-frequency electrodes 25 and the ground electrodes 26. The radicals and ions contained in the generated plasma are supplied to the substrate 11 from the inside of each of the electrode sets 31 and 32, and thereby contaminated substances adhered to the surface of the substrate 11 are removed.

The substrate 11 is cleaned as described above. The process gas is emitted toward the electrode unit 21 through the introduction ports 24, and the process gas is exhausted through the exhaust port 28 located on the opposite side of each of the introduction ports 24 across the electrode unit 21. Therefore, the process gas flows from the front side of the electrode unit 21 through the interval between the first electrode section 31a and the second electrode section 31b arranged vertically in two stages in the upper electrode set 31 to the rear side of the electrode unit 21, for example. Additionally, the process gas is supplied to the inside of the upper electrode set 31 through a plurality of the introduction ports 24 facing the upper electrode set 31.

Thus, the process gas is efficiently made into plasma inside the upper electrode set 31, and the plasma region is generated to be uniformly spread inside the upper electrode set 31. The plasma (i.e. radicals and ions) is supplied from the plasma region uniformly and sufficiently to each part of the upper surface of the substrate 11. Therefore, the upper surface of the substrate 11 is uniformly cleaned by the plasma. Further, since the substrate 11 is cleaned with sufficient amount of plasma, the plasma treatment is completed in a short time. Since the plasma treatment is completed in a short time, the substrate 11 is hardly affected by heat generated in each of the electrodes 25 and 26. Moreover, unlike the case where the substrate 11 is disposed in the plasma region, the damage to the substrate 11 caused by the plasma is little. Similarly, since the process gas flows into the lower electrode set 32 and plasma is generated, the lower surface of the substrate 11 is also cleaned uniformly in a short time.

After the substrate 11 is subjected to the plasma treatment as described above, the supply of the process gas, the exhaust of air, and application of the high-frequency voltage are stopped. Then, after the pressure inside the treatment chamber 14 returns to the atmospheric pressure, the lid 15b is pivoted to the opened position, to open the treatment chamber 14. Then, the substrate 11 subjected to the plasma cleaning is taken out from the treatment chamber 14.

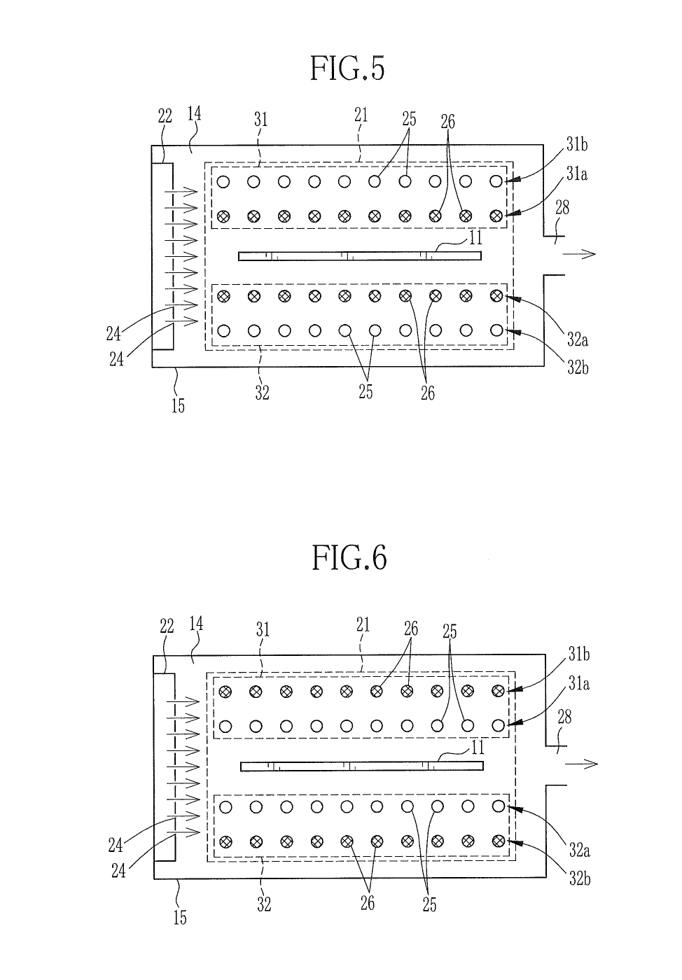

The electrodes different in polarity, namely, the first electrode (high-frequency electrode) and the second electrode (ground electrode) are alternately arranged to constitute each of the electrode sections in the above embodiment. However, it is also possible to adopt various types of arrangement of the first and second electrodes. According to examples shown in FIGS. 5 and 6, the electrode section consists of a plurality of electrodes of the same type, and the electrode sections different in the type of electrodes are disposed to be separated from each other in the electrode set.

In the example shown in FIG. 5, the first electrode section 31a of the upper electrode set 31, which is close to the substrate 11, consists of only the ground electrodes 26, and the second electrode section 31b, which faces the substrate 11 across the first electrode section 31a, consists of only the high-frequency electrodes 25. Similarly, the first electrode section 32a of the lower electrode set 32 consists of only the ground electrodes 26, and the second electrode section 32b, which faces the substrate 11 across the first electrode section 32a, consists of only the high-frequency electrodes 25. In the example shown in FIG. 6, in contrast to the example shown in FIG. 5, each of the first electrode sections 31a and 32a consists of only the high-frequency electrodes 25, and each of the second electrode sections 31b and 32b consists of only the ground electrodes 26.

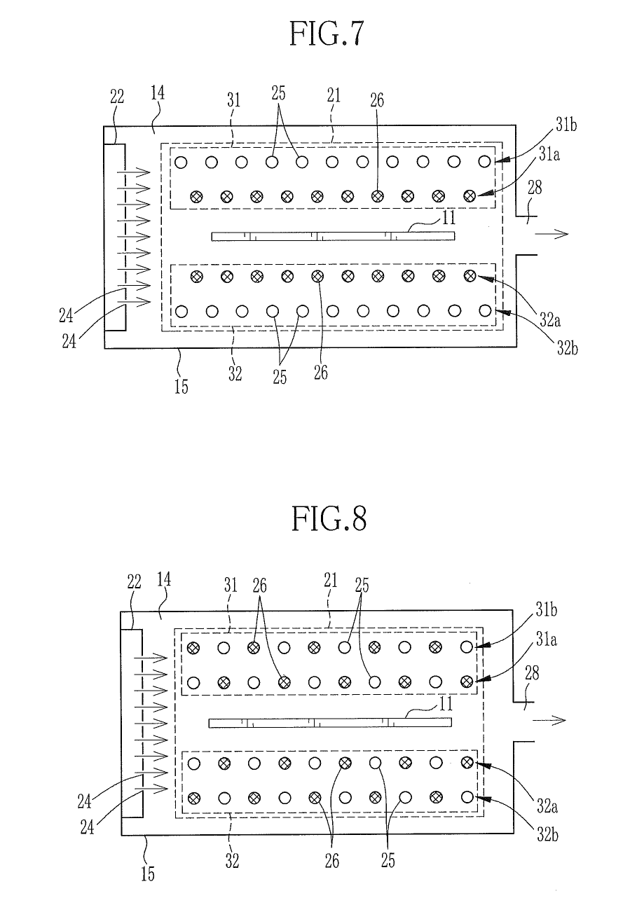

FIG. 7 shows an electrode unit in which the position of each of the electrodes in the first electrode section is deviated from the position of each of the electrodes in the second electrode section in each of the electrode sets 31 and 32. In this example, similarly to the example shown in FIG. 5, each of the first electrode sections 31a and 32a consists of only the ground electrodes 26, and each of the second electrode sections 31b and 32b consists of only the high-frequency electrodes 25. The electrodes are arranged at the same pitch in each of the electrode sections 31a, 31b, 32a, and 32b. The position of each of the electrodes in the first electrode section 31a is deviated from the position of each of the electrodes in the second electrode section 31b by half of the arrangement pitch of the electrodes. Similarly, the position of each of the electrodes in the first electrode section 32a is deviated from the position of each of the electrodes in the second electrode section 32b with a deviation degree corresponding to half of the arrangement pitch of the electrodes.

FIG. 8 shows an electrode unit in which the arrangement of the electrodes is deviated between the electrode sections in each of the electrode sets 31 and 32. In this example, the high-frequency electrode 25 and the ground electrode 26 are alternatively arranged in each of the first electrode section 31a and the second electrode section 31b in the upper electrode set 31. The alternate arrangement of the high-frequency electrodes 25 and the ground electrodes 26 is deviated between the first electrode section 31a and the second electrode section 31b with a deviation degree corresponding to one electrode. Thereby, the high-frequency electrode 25 and the ground electrode 26 are adjacent to each other in the vertical direction. The same holds true for the first electrode section 32a and the second electrode section 32b in the lower electrode set 32.

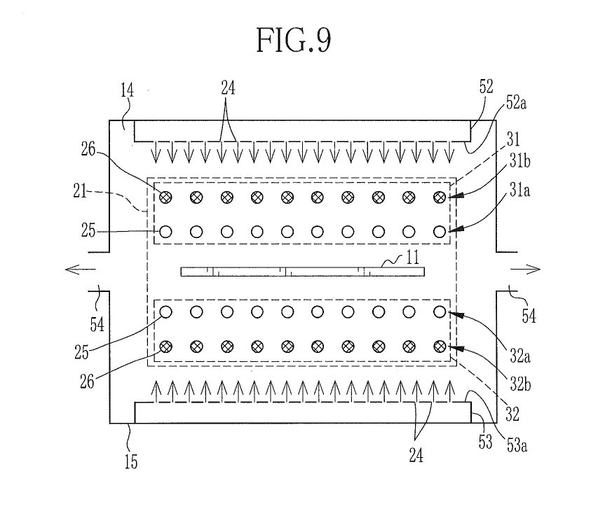

FIG. 9 shows an example in which the process gas is emitted toward the workpiece through the introduction ports disposed so as to be opposed to the workpiece across the electrode set. Namely, the process gas passes through the electrode set before reaching the workpiece. In this example, an upper gas introducing section 52 is provided to the upper surface of the inside of the treatment chamber 14, and a lower gas introducing section 53 is provided to the lower surface of the inside of the treatment chamber 14. Additionally, an exhaust port 54 is provided to front and rear sides of the treatment chamber 14. The process gas is supplied from the gas feeder 17 to the hollow portion of each of the gas introducing sections 52 and 53. The arrangement of the electrodes in each of the upper electrode set 31 and the lower electrode set 32 is the same as that shown in FIG. 6, but is not limited thereto.

A lower surface 52a of the upper gas introducing section 52, which faces the upper electrode set 31, includes a plurality of minute introduction ports 24. The process gas is emitted through each of the introduction ports 24 in a downward direction, namely, in the direction vertical to the substrate 11, such that the process gas passes through the upper electrode set 31 before reaching the substrate 11. The plurality of minute introduction ports 24 are distributed in an area of the lower surface 52a facing the upper electrode set 31, such that the process gas is uniformly supplied to the whole upper electrode set 31.

An upper surface 53a of the lower gas introducing section 53, which faces the lower electrode set 32, includes a plurality of minute introduction ports 24 distributed in an area facing the lower electrode set 32 in the similar manner as the lower surface 52a of the upper gas introducing section 52. The process gas is emitted through each of the introduction ports 24 of the lower gas introducing section 53 in an upper direction, namely, in the direction vertical to the substrate 11, such that the process gas passes through the lower electrode set 32 before reaching the substrate 11.

According to the above configuration, the process gas introduced through the introduction ports 24 of the upper gas introducing section 52 is uniformly supplied into the upper electrode set 31 from above, and excited into plasma in the electric field generated between the high-frequency electrodes 25 and the ground electrodes 26. In a macro perspective, the generated plasma proceeds to the upper surface of the substrate 11 by the gas flow of the process gas from the upper gas introducing section 52, and further flows along the upper surface of the substrate 11 toward the exhaust port 54. Thereby, the sufficient amount of plasma is uniformly supplied to the upper surface of the substrate 11, such that the upper surface of the substrate 11 is uniformly and sufficiently cleaned.

Similarly, the process gas introduced through the introduction ports 24 of the lower gas introducing section 53 is uniformly supplied into the lower electrode set 32 from below, and plasma is generated. The generated plasma proceeds to the lower surface of the substrate 11 by the gas flow of the process gas from the lower gas introducing section 53, and further flows along the lower surface of the substrate 11 toward the exhaust port 54. Thereby, the sufficient amount of plasma is uniformly supplied to the lower surface of the substrate 11, such that the lower surface of the substrate 11 is uniformly and sufficiently cleaned.

Note that, according to the above example, each of the first electrode sections 31a and 32a consists of the high-frequency electrodes 25, and each of the second electrode sections 31b and 32b consists of the ground electrodes 26. However, the present invention is not limited thereto. For example, each of the first electrode sections 31a and 32a may consist of the ground electrodes 26, and each of the second electrode sections 31b and 32b may consist of the high-frequency electrodes 25 as in the case of the example shown in FIG. 5. Alternatively, the arrangement of the electrodes shown in FIGS. 4, 7, and 8 may be adopted.

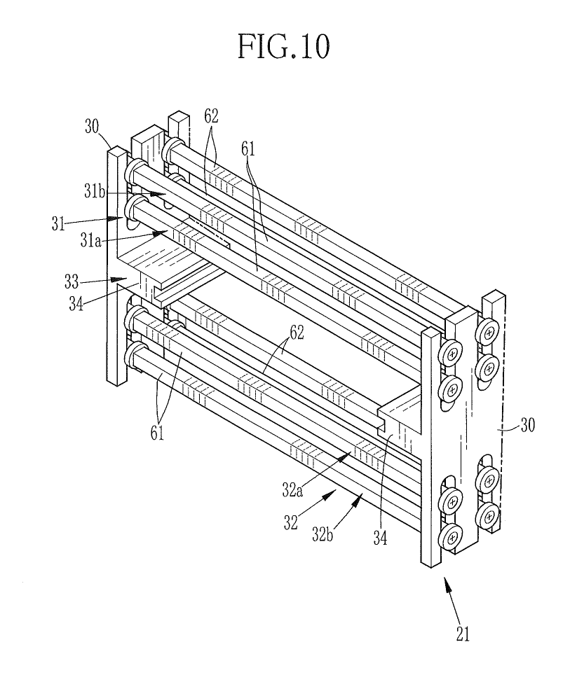

Although each of the electrodes has a cylindrical shape in each of the above embodiments, the shape of each of the electrodes is not limited thereto. For example, each of the electrodes may be a rectangular column such as high-frequency electrodes 61 and ground electrodes 62 shown in FIG. 10, or an elongated plate. Alternatively, the electrode may be a hollow cylinder.

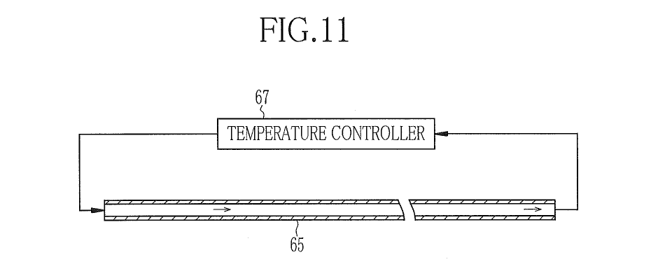

FIG. 11 shows an example in which a heating medium is supplied into the hollow portion of a cylindrical electrode so as to control the temperature of the electrode. An electrode 65 is a hollow cylinder having an opening at each end. The electrode 65 is disposed as the high-frequency electrode or the ground electrode in the treatment chamber 14 in a state that each end of the electrode 65 is connected to a temperature controller 67 through a pipe (not shown in the drawing). Cooling water as the heating medium is supplied to the electrode 65 from the temperature controller 67. The cooling water passes through the inside of the electrode 65, and then returns to the temperature controller 67. The temperature controller 67 adjusts the temperature and flow rate of the cooling water in order to prevent the temperature of the electrode 65 from being too high and maintain the temperature of the electrode 65 within a predetermined range based on the temperature of the cooling water returning to the temperature controller 67. Thereby, it is possible to reduce the influence on the workpiece such as the substrate, which is caused by the high temperature of the electrode 65.

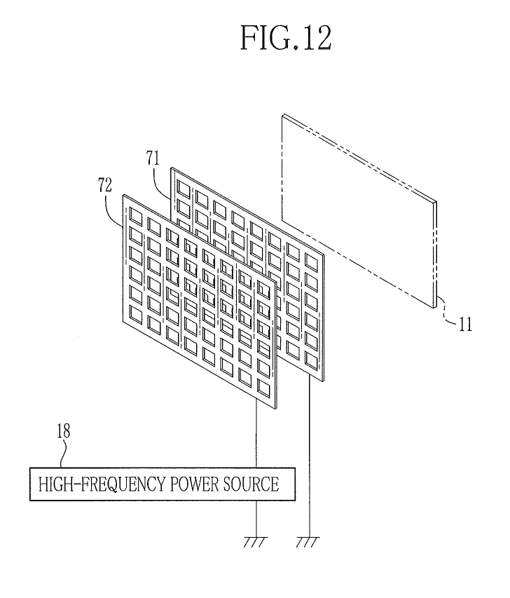

FIG. 12 shows an example using a plate-like electrode provided with a plurality of openings. In this example, each of an inner electrode plate 71 as the first electrode section and an outer electrode plate 72 as the second electrode section has a lattice shape, which is obtained by forming a plurality of rectangular openings in a plate member having conductive properties. The inner electrode plate 71 is disposed at a position facing the surface of the substrate 11 to be treated in a state of being in parallel with the substrate 11. The outer electrode plate 72 is disposed at a position facing the surface of the substrate 11 to be treated across the inner electrode plate 71 in a state of being in parallel with the substrate 11. The inner electrode plate 71 is disposed to be separated from the substrate 11, and the outer electrode plate 72 is disposed to be separated from the inner electrode plate 71. In this case, the process gas emitting direction may be a direction parallel to the substrate 11 or a direction vertical to the substrate 11. Note that, the inside of each of the electrode plates 71 and 72 may be hollow so as to supply cooling water to the inside of each of the electrode plates 71 and 72, for the purpose of controlling the temperature of each of the electrode plates 71 and 72 as in the case shown in FIG. 11.

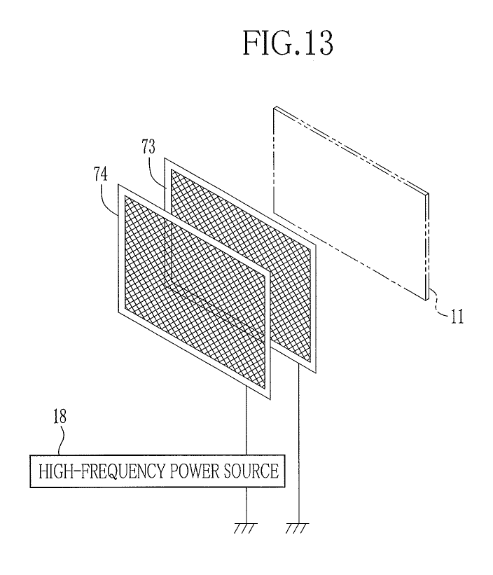

Although each of the electrode plates 71 and 72 has rectangular openings, the openings of each of the electrode plates 71 and 72 may have a circular shape, a triangular shape, or the like. Further, the openings are not necessarily formed regularly, and may be formed in a random manner. As the lattice shape, a mesh may be adopted. Each of electrode plates 73 and 74 shown in FIG. 13 is of mesh type. The size of the opening and the roughness of the mesh of each of the electrode plates may be varied.

In the case where the process gas is emitted in the direction parallel to the substrate, that is, in the direction parallel to each of the electrode plates, the outer electrode plate may be configured without openings. Further, as the first electrode section to be disposed between the plate-like outer electrode plate and the substrate, an electrode array in which a plurality of electrodes in the shape of a rod are arranged as described in the above embodiments may be used instead of the inner electrode plate. Further, in the case where the surface to be treated of the workpiece is curved, each of the electrode plates may be curved along the curved surface to be treated.

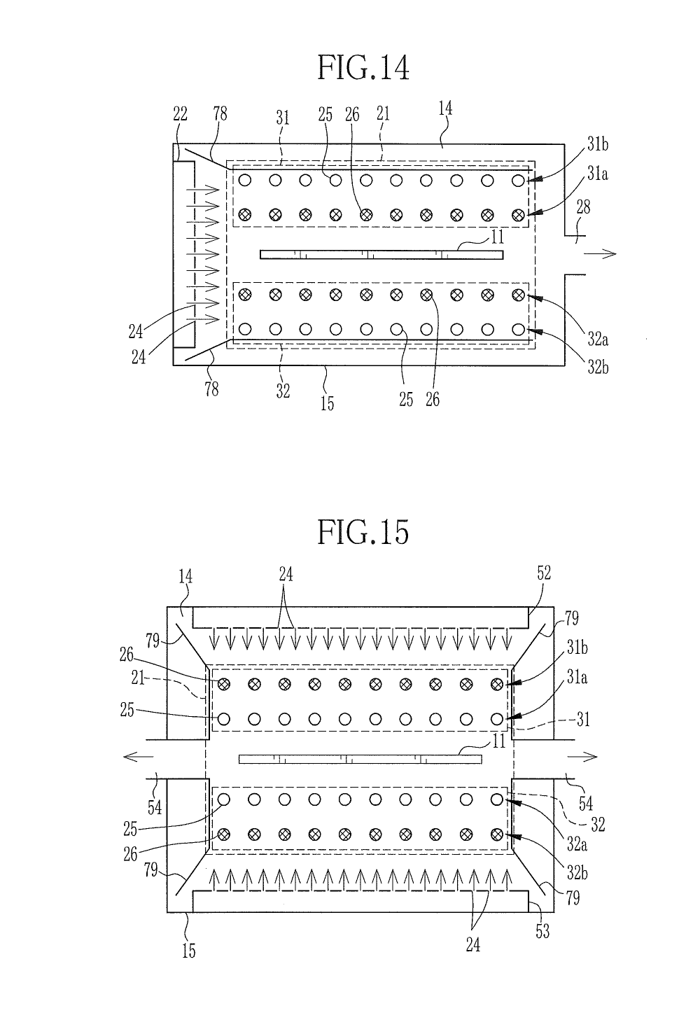

FIG. 14 shows an example in which a flow channel control member for restricting a flow channel of the process gas is disposed in the treatment chamber 14. In this example, as the flow channel control member, a pair of flow channel control plates 78 is disposed. The flow channel control plate 78 at the side of the upper electrode set 31 is disposed above and in proximity to the upper electrode set 31, and extends in a direction from the gas introducing section 22 to the exhaust port 28. The flow channel control plate 78 at the side of the lower electrode set 32 is disposed under and in proximity to the lower electrode set 32, and extends in the direction from the gas introducing section 22 to the exhaust port 28. The end portions of the pair of flow channel control plates 78 at the side of the gas introducing section 22 are directed upward and downward, respectively. The flow channel control plates 78 described above are configured to supply the process gas emitted from the gas introducing section 22 to the inside of the electrode unit 21 and restrict the flow channel of the process gas such that the process gas supplied to the inside of the electrode unit 21 does not flow out of the electrode unit 21 to the outside. Thereby, a uniform flow of the process gas is established in the electrode unit 21. Namely, the flow channel control plates 78 are configured to prevent generation of gas flow, in which the process gas supplied through each of the introduction ports 24 flows above or below the electrode unit 21 and reaches the exhaust port 28 directly, in order to supply efficiently and certainly the process gas to the inside of the electrode unit 21.

In the example shown in FIG. 14 as described above, the process gas emitting direction from the introduction ports 24 corresponds to the direction in which the electrodes are arranged in the electrode section. However, the process gas from the introduction ports 24 may be emitted toward the substrate 11 through the electrode sets 31 and 32, as shown in FIG. 15. In an example shown in FIG. 15, each of the upper gas introducing section 52 and the lower gas introducing section 53 is provided with a pair of flow channel control plates 79, in order to prevent the process gas from flowing between the electrode unit 21 and the front surface of the treatment chamber 14 and between the electrode unit 21 and the rear surface of the treatment chamber 14. Thereby, the process gas is supplied sufficiently and certainly to the inside of the electrode unit 21.

Note that, in the case where there is a gap between each side surface of the electrode unit 21 and the treatment chamber 14 through which the process gas passes, it is sufficient to provide a flow channel control plate so as to prevent the process gas from flowing into the gap. Further, in the case where there is a gap between the treatment chamber 14 and each of the upper surface, the lower surface, and side surfaces of the electrode unit 21, the flow channel control plate may be provided so as to correspond to each of the gaps. However, alternatively, a cylindrical flow channel control member, which is equivalent to the flow channel control plates integrated together, may be used.

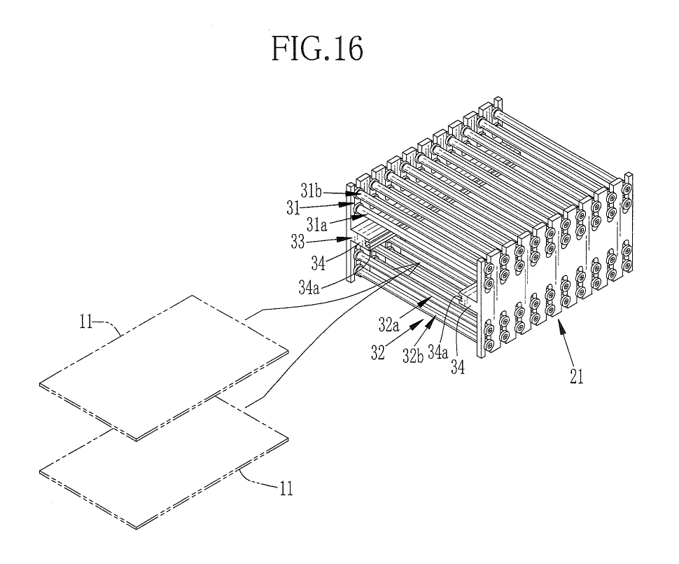

In the above embodiments, both surfaces of a single substrate is subjected to the plasma treatment. However, in the case where the plasma should be supplied to only one surface of the substrate, two substrates 11 can be subjected to the plasma treatment at a time, for example, in an example shown in FIG. 16. Namely, according to the example shown in FIG. 16, two substrates 11 are superimposed to each other and held by the holder 33, in a state that the surface to which the plasma is not supplied of one of the two substrates 11 faces the surface to which the plasma is not supplied of the other of the two substrates 11, and the surface to which the plasma is supplied of each of the two substrates 11 is directed to the outside, and then the two substrates 11 are subjected to the plasma treatment. Note that, in this case, the width of each of the grooves 34a should be at least the total thickness of the two substrates 11 in order to hold the substrates 11 superimposed to each other by the holder 33 at a time.

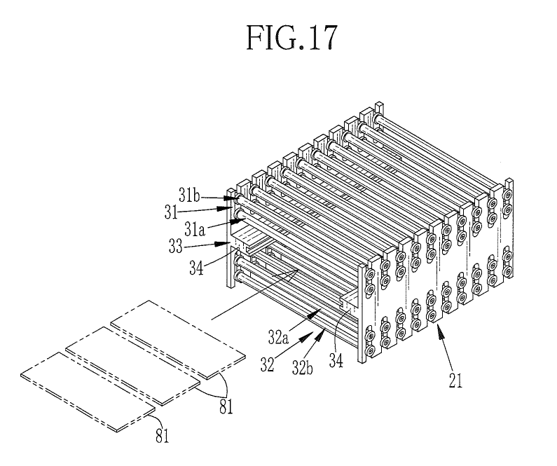

Further, as shown in FIG. 17, a plurality of substrates 81 each having a small size are held by the holder 33 so as not to be overlapped with each other, in a state that the surfaces of each of the substrates to which the plasma is supplied face the electrode sets 31 and 32 respectively, and then the substrates 81 may be subjected to the plasma treatment at a time. In the case where each of the substrates 81 has only one surface to which the plasma is supplied, two substrates 81 in a state that the surface which is not subjected to the treatment of one of the two substrates 81 faces the surface which is not subjected to the treatment of the other of the two substrates 81 are grouped into one pair as with the example shown in FIG. 16, and then a plurality pairs of the substrates 81 may be held by the holder 33.

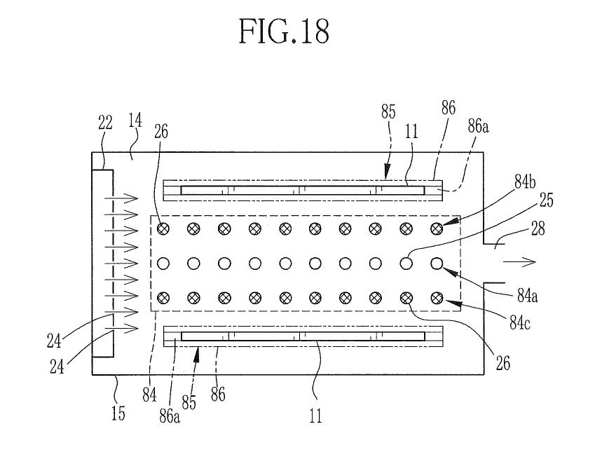

FIG. 18 shows an example in which two workpieces each having only one surface to which the plasma is supplied are held, in a state that the surface to which the plasma is supplied of one of the two workpieces faces the surface to which the plasma is supplied of the other of the two workpieces across the electrode set. In this example, an electrode set 84 is disposed in the treatment chamber 14. The electrode set 84 includes a first electrode section 84a, a second electrode section 84b, and a third electrode section 84c. The first electrode section 84a consists of only the high-frequency electrodes 25, and each of the second electrode section 84b and the third electrode section 84c consists of only the ground electrodes 26. The orientation of the electrodes in each of the first to third electrode sections 84a to 84c is the same as that in the first embodiment. The second electrode section 84b is disposed above the first electrode section 84a with an appropriate interval therebetween, and the third electrode section 84c is disposed under the first electrode section 84a with an appropriate interval therebetween. Note that, the first electrode section 84a may consist of only the ground electrodes 26, and each of the second electrode section 84b and the third electrode section 84c may consist of only the high-frequency electrodes 25.

A pair of holders 85 is disposed so as to sandwich the electrode set 84 disposed in the treatment chamber 14 described above. Each of the holders 85 has the same structure as that of the holder 33 of the first embodiment, for example, and consists of a pair of rail members 86 each having a groove 86a. The substrate 11 is set one-by-one to each of the holders 85 in a state that the surface to be treated of the substrate 11 faces the electrode set 84. Namely, one of the substrates 11 is set above the second electrode section 84b with an appropriate interval therebetween in a state that the surface to which the plasma is supplied is directed downward, and the other of the substrates 11 is set under the third electrode section 84c with an appropriate interval therebetween in a state that the surface to which the plasma is supplied is directed upward. According to the configuration as described above, it is possible to subject one surface of each of the two substrates 11 to the plasma treatment at a time with use of one electrode set 84.

In the example shown in FIG. 18 described above, three electrode arrays (i.e. electrode sections) are symmetrically disposed in the electrode set 84, such that the treatment speed is the same between the two substrates 11. However, an electrode set having the arrangement of the electrode arrays similar to that shown in FIGS. 4 and 8 may be used. In the examples shown in FIGS. 16 to 18, the surface to which the plasma is supplied may be equivalent to the surface to be treated itself, or a surface to which the plasma is primarily supplied.

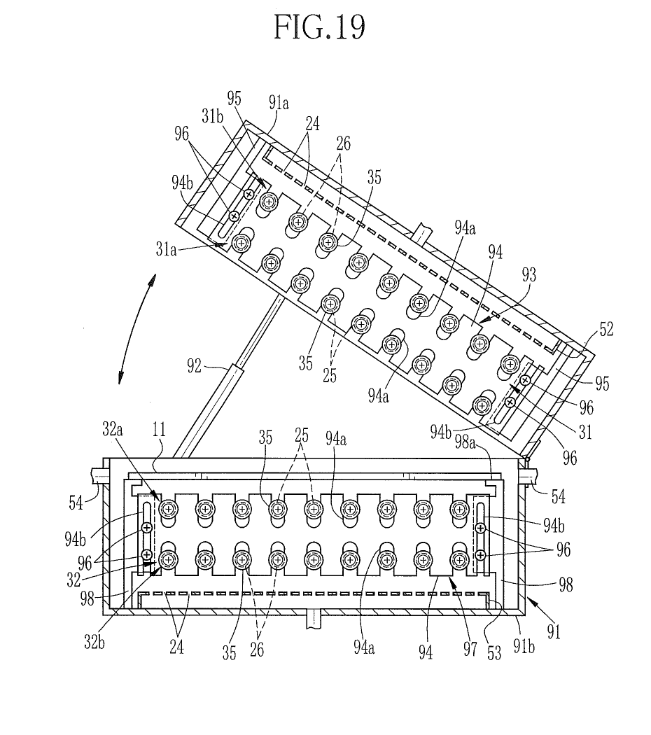

FIG. 19 shows an example in which the upper electrode set and the lower electrode set are configured as separated units. Except the explanation below, the configuration shown in FIG. 19 is the same as that shown in FIG. 9, and therefore substantially the same components as those shown in FIG. 9 are denoted by the same reference numerals respectively, and the detailed explanation thereof will be omitted. Further, the arrangement of the electrodes, the process gas introducing direction, and the like of other examples may be adopted.

A vacuum tank 91 has a box shape to be divided into two parts in a vertical direction, namely, consists of an upper vacuum tank 91a and a lower vacuum tank 91b. The upper vacuum tank 91a is pivotable between an opened position at which the treatment chamber 14 is in an opened state and a closed position at which the treatment chamber 14 is air-tightly closed through a hinge attached to a lower portion of a back surface of the upper vacuum tank 91a and an upper portion of a back surface of the lower vacuum tank 91b as shown in the drawing. With use of a hydraulic cylinder 92, the upper vacuum tank 91a is moved between the opened position and the closed position. Note that, not only the hydraulic cylinder 92 but also various kinds of actuators may be used to open and close the vacuum tank 91.

An upper electrode unit 93 is attached to the inside of the upper vacuum tank 91a. The upper electrode unit 93 includes a first electrode section 31a and a second electrode section 31b for constituting the upper electrode set 31, and a pair of side plates 94 to which each of the high-frequency electrodes 25 of the first electrode section 31a and each of the ground electrodes 26 of the second electrode section 31b are assembled. Each end of each of the electrodes 25 and 26 is fit into a mounting groove 94a having a U-shape formed in each of the side plates 94 through the bushing 35. In this example, the mounting groove 94a having a U-shape is formed for each of the electrodes 25 and 26. Namely, the mounting groove 94a obtained by making a cut from the lower end of the side plate 94 is provided for each of the electrodes 25 of the first electrode section 31a, and the mounting groove 94a obtained by making a cut from the upper end of the side plate 94 is provided for each of the electrodes 26 of the second electrode section 31b. Thereby, each of the electrodes 25 and 26 can be taken out one-by-one.

A mounting groove 94b extending in the vertical direction is formed in a front end portion and a rear end of portion of each of the side plates 94. A stay 95 is formed at four corners of the upper vacuum tank 91a, and a screw 96 is threadably mounted on each of the stays 95. The screw 96 is inserted through each of the mounting grooves 94b. Thereby, the upper electrode unit 93 is movable in the vertical direction in the state that the upper vacuum tank 91a is located at the closed position, namely, the upper electrode unit 93 is movable in a direction for increasing/decreasing the distance between the upper vacuum tank 91a and the substrate 11 held by the upper portion of the lower vacuum tank 91b. The upper electrode unit 93 is moved in the vertical direction along the mounting groove 94b by loosening the screw 96, and the upper electrode unit 93 is fixed to an arbitrary position by tightening the screw 96. Thereby, it is possible to adjust the interval between the upper surface of the substrate 11 and the upper electrode set 31.

A lower electrode unit 97 having the same structure as that of the upper electrode unit 93 is attached to the inside of the lower vacuum tank 91b. Namely, the lower electrode unit 97 includes a first electrode section 32a and a second electrode section 32b for constituting the lower electrode set 32, and a pair of side plates 94 to which each of the high-frequency electrodes 25 of the first electrode section 32a and each of the ground electrodes 26 of the second electrode section 32b are assembled. A stay 98 is formed at four corners of the lower vacuum tank 91b, and a screw 96 is threadably mounted on each of the stays 98, such that the lower electrode unit 97 is movable in the vertical direction and fixed to an arbitrary position. Thereby, it is possible to adjust the interval between the lower surface of the substrate 11 and the lower electrode set 32.

The upper gas introducing section 52 is attached to the upper surface of the inside of the upper vacuum tank 91a. The process gas emitted through each of the introduction ports 24 provided to the upper gas introducing section 52 passes through the upper electrode unit 93 toward the upper surface of the substrate 11. Further, the lower gas introducing section 53 is attached to the lower surface of the inside of the lower vacuum tank 91b. The process gas emitted through each of the introduction ports 24 provided to the lower gas introducing section 53 passes through the lower electrode unit 97 toward the lower surface of the substrate 11.

A mounting surface 98a for mounting the substrate 11 is formed on an upper end of each of the stays 98. The four corners of the substrate 11 to be treated are mounted on the mounting surfaces 98a, and the substrate 11 is subjected to the plasma treatment. An exhaust port 54 is provided to each of the front side of the vacuum tank 91 facing the center of the front end of the substrate 11 mounted on the mounting surfaces 98a and the back side of the vacuum tank 91 facing the center of the back end of the substrate 11 mounted on the mounting surfaces 98a.

According to this example, in each of the electrode units 93 and 97, the electrodes 25 and 26 are moved so as to adjust the interval between the electrodes 25 and 26 in the vertical direction. Further, since the upper electrode unit 93 and the lower electrode 97 are integrated together and moved in the vertical direction, the interval between the upper electrode set 31 and the upper surface of the substrate 11 and the interval between the lower electrode set 32 and the lower surface of the substrate 11 are adjusted. In the case of subjecting the substrate 11 to the plasma treatment, after the four corners of the substrate 11 are mounted on the mounting surfaces 98a so as to be held thereon, the upper vacuum tank 91a is set to the closed position, and the substrate 11 is subjected to the plasma treatment in the similar manner as the embodiments described above.

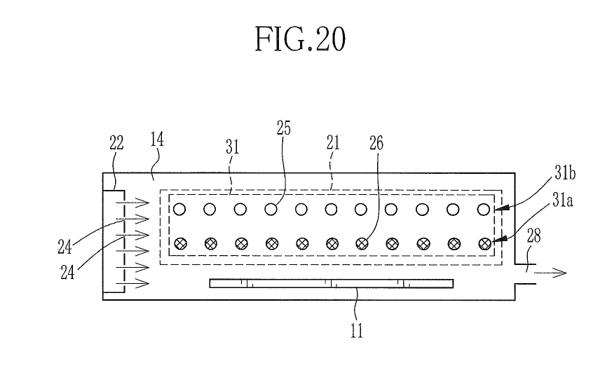

FIG. 20 shows an example, in which the electrode set is disposed so as to face only one surface of the workpiece. In this example, only the upper electrode set 31 corresponding to the upper surface of the substrate 11 is disposed, such that only the upper surface of the substrate 11 is subjected to the plasma treatment. Note that, except the condition that the lower electrode set is not provided, the configuration of this example is the same as that of the example shown in FIG. 5, and therefore substantially the same components as those shown in FIG. 5 are denoted by the same reference numerals respectively, and the detailed explanation thereof will be omitted. Further, although the upper electrode set is disposed so as to face only the upper surface of the substrate 11 in this example, the configuration in which the electrode set 31 is disposed so as to face only one surface to be treated of the workpiece may be adopted. Furthermore, the process gas introducing direction is not limited to that shown in the drawing, and the process gas may be emitted toward the workpiece through the electrode set.

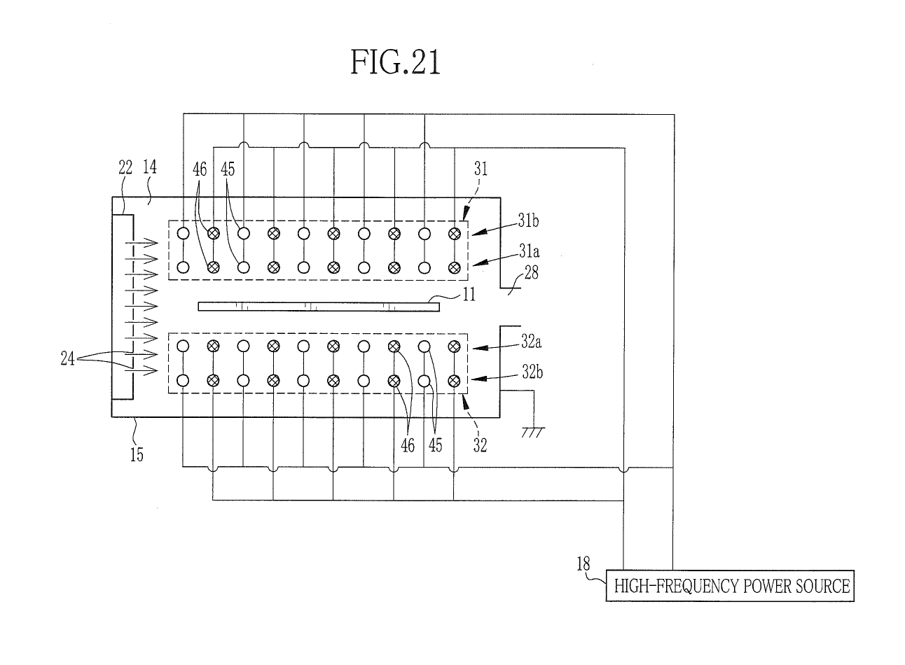

In the above embodiments, one of the electrodes different in polarity is grounded and considered as the ground electrode. However, as shown in an example in FIG. 21, electrodes 45 and 46 different in polarity, which are connected to the high-frequency power source 18, may not be grounded. According to such a configuration, each of the electrodes 45 and 46 is electrically insulated from the grounded vacuum tank 15.

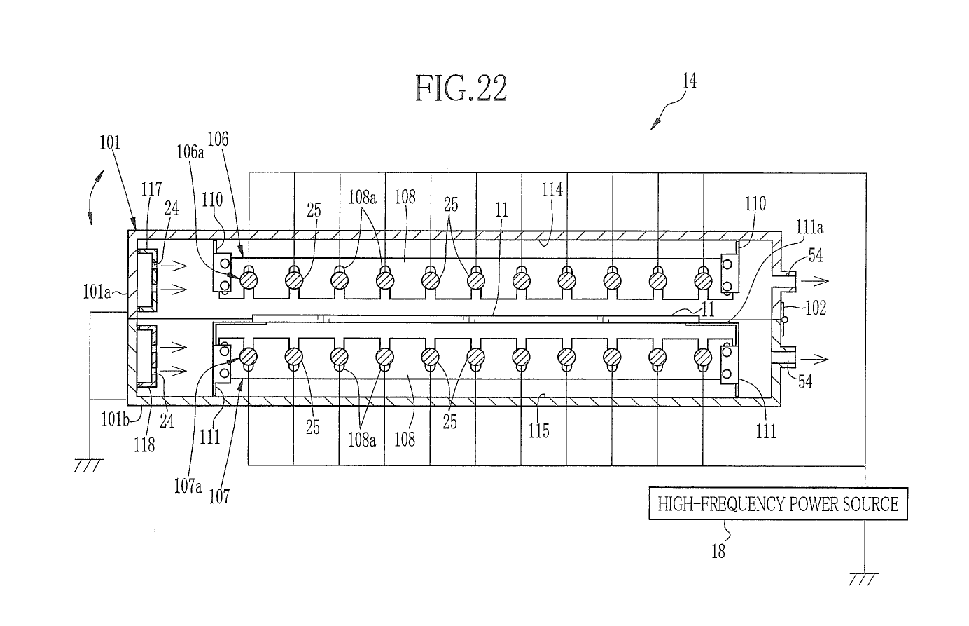

FIG. 22 shows an example in which an inner wall surface of the treatment chamber 14 is used as the ground electrodes. Except the explanation below, the configuration shown in FIG. 22 is the same as that shown in FIG. 19, and therefore substantially the same components as those shown in FIG. 19 are denoted by the same reference numerals respectively, and the detailed explanation thereof will be omitted.

A vacuum tank 101 has a thin box shape which is divided into two parts in the vertical direction, and consists of an upper vacuum tank 101a and a lower vacuum tank 101b. The upper vacuum tank 101a is pivotable between an opened position at which the treatment chamber 14 is in an opened state and a closed position at which the treatment chamber 14 is air-tightly closed through a hinge 102 attached to at the back side of the vacuum tank 101 as shown in the drawing. With use of an actuator (not shown in the drawing), the upper vacuum tank 101a is moved between the opened position and the closed position.

An upper electrode unit 106 is disposed inside the upper vacuum tank 101a, and a lower electrode unit 107 is disposed inside the lower vacuum tank 101b. The upper electrode unit 106 includes an upper electrode section 106a and a pair of side plates 108 for holding both ends of each of the high-frequency electrodes 25 of the upper electrode section 106a. The structure of the lower electrode unit 107 is similar to that of the upper electrode unit 106. The lower electrode unit 107 includes a lower electrode section 107a and a pair of side plates 108, such that a plurality of the high-frequency electrodes 25 of the lower electrode section 107a are held between the pair of side plates 108. The high-frequency electrodes 25 of the upper electrode section 106a and the high-frequency electrodes 25 of the lower electrode section 107a are disposed in parallel with each other in a state of being separated from each other. The high-frequency electrodes 25 are positive electrodes (i.e. anode electrodes), for example. Note that, in FIG. 22, the side plate 108 located at the front side in a direction perpendicular to the sheet of the drawing is not shown, and only the side plate 108 located at the back side is shown.

In the upper electrode unit 106, the front end and the rear end of each of the side plates 108 are fixed to stays 110 formed at four corners of the upper vacuum tank 101a. In the lower electrode unit 107, the front end and the rear end of each of the side plates 108 are fixed to stays 111 formed at four corners of the lower vacuum tank 101b. A mounting surface 111a is formed on an upper end of each of the stays 111. The four corners of the substrate 11 to be treated are mounted on the mounting surfaces 111a, such that the substrate 11 is housed in a horizontal posture in the treatment chamber 14 in a state that the upper surface of the substrate 11 faces the upper electrode section 106a and the lower surface of the substrate 11 faces the lower electrode section 107a.

The mounting position of each of the high-frequency electrodes 25 of the upper electrode section 106a in a mounting groove 108a is adjusted, such that the high-frequency electrodes 25 are aligned in the horizontal direction in a state that the upper vacuum tank 101a is located at the closed position. Accordingly, the upper electrode section 106a and the high-frequency electrodes 25 thereof are disposed in parallel with the upper surface of the substrate 11 placed in a horizontal posture in the treatment chamber 14. Similarly, the mounting position of each of the high-frequency electrodes 25 of the lower electrode section 107a in amounting groove 108a is adjusted such that the high-frequency electrodes 25 are aligned in the horizontal direction. The lower electrode section 107a and the high-frequency electrodes 25 thereof are disposed in parallel with the lower surface of the substrate 11.

A ceiling surface 114 of the inner wall surface of the treatment chamber 14, which is opposed to the substrate 11 across the upper electrode 106a, is a plane in parallel with the upper electrode section 106a. The interval between each of the high-frequency electrodes 25 of the upper electrode section 106a and the ceiling surface 114 is constant. Similarly, a bottom surface 115 of the inner wall surface of the treatment chamber 14, which is opposed to the substrate 11 across the lower electrode section 107a, is a plane in parallel with the lower electrode 107a. The interval between each of the high-frequency electrodes 25 of the lower electrode section 107a and the bottom surface 115 is constant.

Each of the upper vacuum tank 101a and the lower vacuum tank 101b is made of a material having conductive properties and grounded. Accordingly, the ceiling surface 114 functions as a ground electrode corresponding to each of the high-frequency electrodes 25 of the upper electrode section 106a, and the bottom surface 115 functions as a ground electrode corresponding to each of the high-frequency electrodes 25 of the lower electrode section 107a. According to the configuration in which the inner wall surface of the vacuum tank 101 is used as the ground electrodes as described above, it is possible to decrease the number of components. Therefore, the configuration described above is advantageous in making the plasma treatment apparatus thinner and smaller.

In this example, each of the ceiling surface 114 and the bottom surface 115 corresponds to the second electrode section. The upper electrode section 106a and the ceiling surface 114 constitute the upper electrode set, and the lower electrode section 107a and the bottom surface 115 constitute the lower electrode set. Additionally, although the vacuum tank 101 is made of a material having conductive properties as a whole, it is sufficient that only the ceiling surface 114 and the bottom surface 115 have the conductive properties for the purpose of generating plasma.

An upper gas introducing section 117 is disposed at the front side inside the upper vacuum tank 101a, and a lower gas introducing section 118 is disposed at the front side inside the lower vacuum tank 101b. The upper gas introducing section 117 emits the process gas through a plurality of the introduction ports 24 toward the upper electrode section 106a in the direction in which the high-frequency electrodes 25 are aligned, and the lower gas introducing section 118 emits the process gas through a plurality of the introduction ports 24 toward the lower electrode section 107a in the direction in which the high-frequency electrodes 25 are aligned. In this example, the exhaust port 54 is disposed at a position facing the upper gas introducing section 117 across the upper electrode section 106a, namely at the back side of the upper vacuum tank 101a. Similarly, the exhaust port 54 is disposed at a position facing the lower gas introducing section 118 across the lower electrode section 107a, namely at the back side of the lower vacuum tank 101b. Accordingly, the process gas emitted toward the periphery of each of the electrode sections 106a and 107a is efficiently made into plasma, and the plasma region in which the plasma is uniformly distributed is generated.

Each of the high-frequency electrodes 25, the side plates 108, the stays 110 and 111, and the gas introducing sections 117 and 118 is electrically insulated from the vacuum tank 101 and electrically insulated from one another.

According to this example, upon application of the high-frequency voltage to each of the high-frequency electrodes 25 from the high-frequency power source 18, the process gas is excited into plasma in the electric field generated by using the ceiling surface 114 and the bottom surface 115 as the ground electrodes. Then, the radicals and ions contained in the generated plasma are supplied to the substrate 11, and contaminated substances adhered to the surface of the substrate 11 are removed.

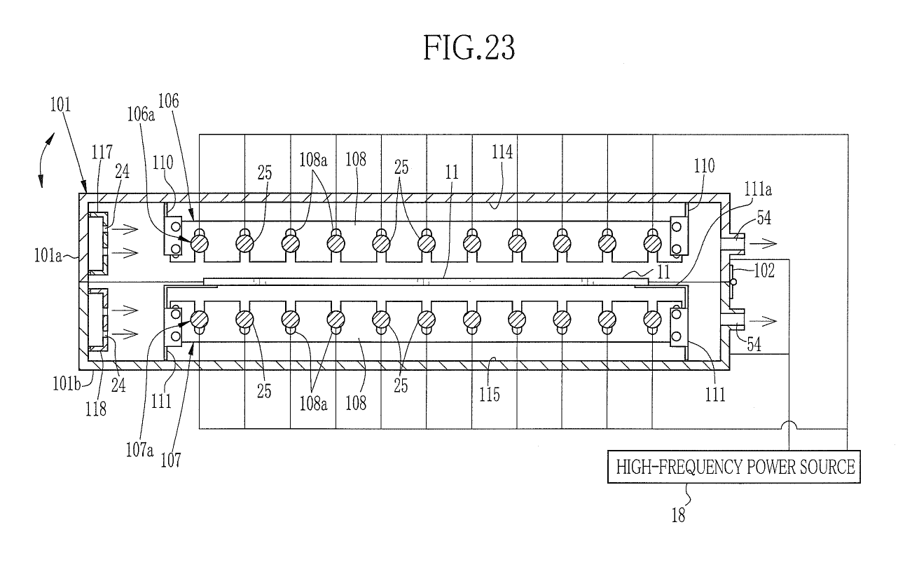

Note that, although the gas introducing sections 117 and 118 are disposed such that the process gas is emitted in the direction in which the electrodes are aligned in the above example, the gas introducing sections may be disposed such that the process gas is emitted in the axial direction of the high-frequency electrodes 25. In this case, it is necessary to hold the high-frequency electrodes 25 so as not to block the flow of the process gas emitted from the gas introducing sections. Further, although the ceiling surface 114 and the bottom surface 115 as the electrodes of the second electrode section are the ground electrodes in the above example, the ceiling surface 114 and the bottom surface 115, in addition to the high-frequency electrodes 25, may not be grounded as shown in FIG. 23. Furthermore, a plate member having a plurality of rectangular openings, such as the inner electrode plate 71 shown in FIG. 12, may be used as the first electrode section.

Although the present invention has been fully described by the way of the preferred embodiment thereof with reference to the accompanying drawings, various changes and modifications will be apparent to those having skill in this field. Therefore, unless otherwise these changes and modifications depart from the scope of the present invention, they should be construed as included therein.

What is claimed is:

1. A plasma treatment apparatus, in which a workpiece is housed in a treatment chamber, and after the treatment chamber is brought into a vacuum state, process gas is introduced into the treatment chamber, so as to generate plasma by the process gas, and the workpiece is subjected to treatment using the plasma, the plasma treatment apparatus comprising:
an introduction port through which the process gas is introduced into the treatment chamber;
a power source for outputting high-frequency voltage intended for generating the plasma; and
an electrode set including a first electrode section having a plurality of electrodes in the shape of a rod arranged in parallel with one another at predetermined intervals and a second electrode section so as to generate the plasma by exciting the process gas by the high-frequency voltage outputted from the power source, the first electrode section being disposed to face the workpiece in a state of being separated from the workpiece, and the second electrode section being disposed to face the workpiece across the first electrode section in a state of being separated from the first electrode section.

2. The plasma treatment apparatus according to claim 1, wherein
the second electrode section has a plurality of electrodes in the shape of a rod arranged in parallel with one another at predetermined intervals, and
the electrodes of each of the first electrode section and the second electrode section are arranged in parallel with a surface of the workpiece.

3. The plasma treatment apparatus according to claim 2, wherein the introduction port is disposed to be opposed to the workpiece across the electrode set, such that the process gas is emitted toward the workpiece through the electrode set.

4. The plasma treatment apparatus according to claim 2, further comprising an exhaust port disposed at a position facing the introduction port across the workpiece, for exhausting air from the treatment chamber, wherein the process gas is emitted through the introduction port toward the electrode set in a direction in which the electrodes of the first and second electrode sections are aligned or in an axial direction of the electrodes.

5. The plasma treatment apparatus according to claim 2, wherein the electrodes different in polarity are alternately arranged to constitute each of the first and second electrode sections.

6. The plasma treatment apparatus according to claim 2, wherein a polarity of each of the electrodes arranged in the first electrode section is different from a polarity of each of the electrodes arranged in the second electrode section.

7. The plasma treatment apparatus according to claim 1, wherein
the second electrode section is an inner wall surface of the treatment chamber, and
the high-frequency voltage is applied from the power source to the electrode set, in which a polarity of each of the electrodes of the first electrode section is different from a polarity of the inner wall surface, to generate the plasma.

8. The plasma treatment apparatus according to claim 7, wherein each of the electrodes of the first electrode section and the inner wall surface are parallel to the surface of the workpiece.

9. The plasma treatment apparatus according to claim 7, further comprising an exhaust port for exhausting air from the treatment chamber, wherein
the process gas is emitted through the introduction port toward the first electrode section in a direction in which the electrodes of the first electrode section are aligned or in an axial direction of the electrodes, and
the exhaust port is disposed at a position facing the introduction port across the first electrode section.

10. The plasma treatment apparatus according to claim 1, wherein the electrode set is disposed at positions for sandwiching the workpiece.

11. The plasma treatment apparatus according to claim 1, wherein the electrode set is disposed only at a position where the electrode set faces one surface of the workpiece.

12. The plasma treatment apparatus according to claim 1, further comprising a holder for holding a pair of the workpieces superimposed to each other in a state that the surface of each of the workpieces is directed to the outside, wherein
the electrode set is disposed so as to face the surface of each of the pair of workpieces held by the holder.

13. The plasma treatment apparatus according to claim 1, further comprising a holder for holding a plurality of workpieces in a state that the surface of each of the workpieces is directed to the electrode set.

14. The plasma treatment apparatus according to claim 1, further comprising a flow channel control member disposed in the treatment chamber, for preventing the process gas emitted through the introduction port from flowing between the electrode set and the treatment chamber toward the exhaust port.

15. A plasma treatment method for subjecting a workpiece, which is housed in a treatment chamber, to treatment using plasma generated in the treatment chamber after being brought into a vacuum state, the plasma treatment method comprising:
an introducing step for introducing process gas into the treatment chamber;
a generating step for generating plasma by exciting the process gas by an electrode set, the electrode set including a first electrode section having a plurality of electrodes in the shape of a rod arranged in parallel with one another at predetermined intervals and a second electrode section, the first electrode section being disposed to face the workpiece in a state of being separated from the workpiece, and the second electrode section being disposed to face the workpiece across the first electrode section in a state of being separated from the first electrode section; and
a treatment step for subjecting the workpiece to the treatment using the generated plasma.

16. The plasma treatment method according to claim 15, further comprising an exhausting step for exhausting air from the treatment chamber while generating the plasma, wherein
the process gas is emitted through the introduction port toward the first electrode section in a direction in which the electrodes of the first electrode section are aligned or in an axial direction of the electrodes in the introducing step, and
air is exhausted through an exhaust port disposed at a position facing the introduction port across the first electrode section in the exhausting step.

17. The plasma treatment method according to claim 15, wherein
the plasma is generated in the electrode set disposed at positions for sandwiching the workpiece in the generating step, and
the workpiece is subjected to treatment using the plasma generated in each of the electrode sets in the treatment step.
